(19) United States
(12) Patent Application Publication
(10) Pub. No.: US 2010/0097116 A1
(43) Pub. Date: Apr. 22, 2010

(54) HIGH SIDE DRIVER WITH SHORT TO GROUND PROTECTION

(76) Inventor: Imad Sharaa, Farmington, MI (US)

Correspondence Address: FRASER CLEMENS MARTIN & MILLER LLC, 28366 KENSINGTON LANE, PERRYSBURG, OH, 43551, US

(21) Appl. No.: 12/254,165

(22) Filed: Oct. 20, 2008

(51) Int. Cl. H03K 3/01

(52) U.S. Cl. 327/333

(57) ABSTRACT

A protection circuit for a high side driver includes an exclusive-OR gate adapted to receive a first input and a second input, analyze each of the inputs and transmit an output in response to the analysis of the inputs, wherein the first input represents an electric power output of the high side driver and the second input represents a control signal for operating the high side driver, and a switching device adapted to control an electrical output of the high side driver in response to the output of the exclusive-OR gate.

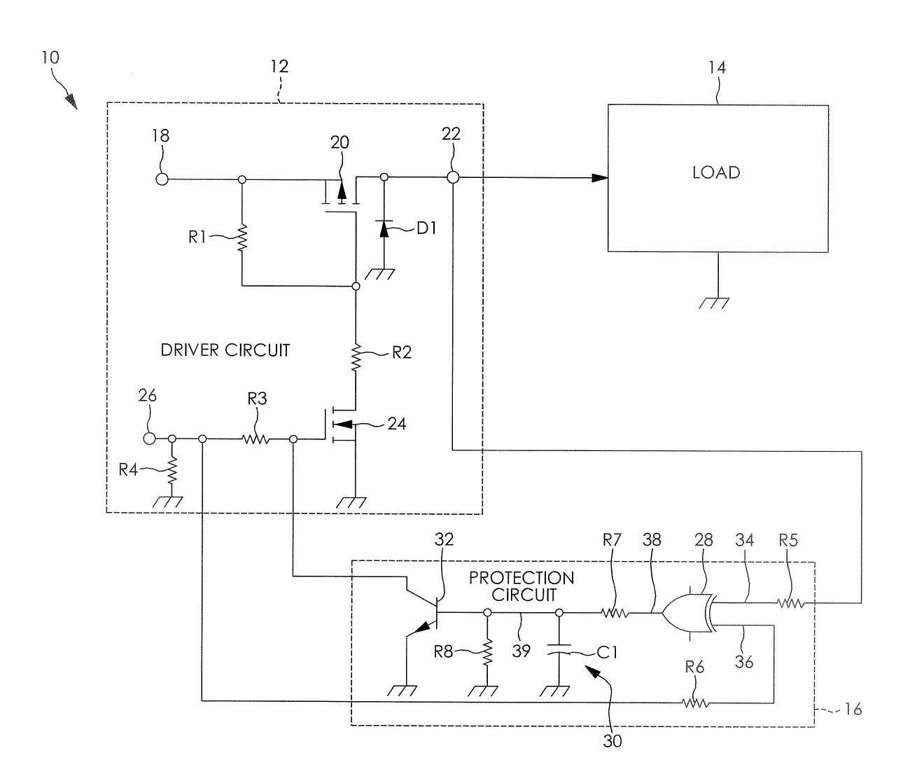

### FIELD OF THE INVENTION

The invention relates to high side drivers. More particularly, the invention is directed to a protection circuit for a high side driver.

### BACKGROUND OF THE INVENTION

Protecting high side drivers in the event of a short to ground can be very costly, especially in high current applications. Some systems and methods require software intervention and others utilize a fully protected expensive device. Certain systems combine several components with software intervention to protect the driver from short to ground on the output. Software based systems are more expensive in terms of the material cost and the number of components required and are not even possible in system designs that do not have microcontrollers. Alternatively, some system designs include a self-protected driver which has a price disadvantage in the automotive competitive world.

It would be desirable to have a cost efficient protection circuit for a high side driver, wherein the protection circuit minimizes the required number of components and does not require software intervention.

### SUMMARY OF THE INVENTION

Concordant and consistent with the present invention, a cost efficient protection circuit for a high side driver, wherein the protection circuit minimizes the required number of components and does not require software intervention, has surprisingly been discovered.

In one embodiment, a protection circuit for a high side driver comprises: an exclusive-OR gate adapted to receive a first input and a second input, analyze each of the inputs and transmit an output in response to the analysis of the inputs, wherein the first input represents an electric power output of the high side driver and the second input represents a control signal for operating the high side driver; and a switching device adapted to control an electrical output of the high side driver in response to the output of the exclusive-OR gate.

In another embodiment, a high side driver comprises: a driver circuit including a first switching device and a second switching device, wherein the first switching device and the second switching device cooperate to control an electrical output of the high side driver; and a protection circuit including: an exclusive-OR gate adapted to receive a first input and a second input, analyze each of the inputs and transmit an output in response to the analysis of the inputs, wherein the first input represents the electric power output of the high side driver and the second input represents a control signal for operating the high side driver; and a third switching device in electrical communication with at least one of the first switching device and the second switching device and adapted to control the at least one of the switching devices in response to the output of the exclusive-OR gate.

In a further embodiment, a high side driver comprises: a driver circuit including a first transistor and a second transistor, wherein the first transistor and the second transistor cooperate to control an electrical output of the high side driver; and a protection circuit including: an exclusive-OR gate adapted to receive a first input and a second input, analyze each of the inputs and transmit an output in response to the analysis of the inputs, wherein the first input represents the electric power output of the high side driver and the second input represents a control signal for operating the high side driver; and a third transistor in electrical communication with at least one of the first transistor and the second transistor and adapted to control the at least one of the switching devices in response to the output of the exclusive-OR gate.

### BRIEF DESCRIPTION OF THE DRAWINGS

The above, as well as other advantages of the present invention, will become readily apparent to those skilled in the art from the following detailed description of the preferred embodiment when considered in the light of the accompanying drawing which is a schematic block diagram of a high side drive in electrical communication with a load according to an embodiment of the present invention.

### DETAILED DESCRIPTION OF EXEMPLARY EMBODIMENTS OF THE INVENTION

The following detailed description and appended drawings describe and illustrate various embodiments of the invention. The description and drawings serve to enable one skilled in the art to make and use the invention, and are not intended to limit the scope of the invention in any manner.

Referring to the FIGURE, there is illustrated a high side driver 10 according to an embodiment of the present invention. As shown, the high side driver 10 includes a driver circuit 12 in electrical communication with a load 14 and a protection circuit 16. However, it is understood that the high side driver 10 may include additional components, as desired. It is further understood that the high side driver 10 may be in communication with other components, systems, loads and power supplies, as desired.

The driver circuit 12 is adapted to regulate and transmit an electric current to the load 14. It is understood that the load 14 may be any device, component, or system, as desired. In the embodiment shown, the driver circuit 12 includes a supply input 18, a first switching device 20, an output 22, a second switching device 24, and a control input 26. As shown, the driver circuit 12 further includes a plurality of resistors R1, R2, R3, R4 for controlling current and a diode D1 for protecting the first switching device 20 by clamping negative voltages on the output 22 that result from switching the first switching device 20 to an “OFF” status when the load 14 is inductive. However, it is understood that the driver circuit 12 may include additional components and systems, as desired. It is further understood that the driver circuit 12 may be in electrical communication with other circuits, systems and components, as desired.

The supply input 18 is in electrical communication with a source of electrical energy (not shown). The supply input 18 provides a supply voltage to the driver circuit 12 and a selective source of electric current to the load 14.

The first switching device 20 is a field-effect transistor. In the embodiment shown, the first switching device 20 is a p-channel MOSFET (Metal Oxide Semiconductor Field Effect Transistor) having a gate, a source, and a drain as known to someone skilled in the art of transistors. However, it is understood that other transistors or switches may be used to regulate the flow of current in the driver circuit 12, as desired. In the embodiment shown, the source of the first switching device 20 is in electrical communication with the supply input 18 and the drain is in electrical communication with the output 22 of the driver circuit 12. Where the gate of the first switching device 20 is grounded and the supply voltage is positive, the gate-source voltage of the first switching device 20 is negative and the first switching device 20 is switched “ON”, thereby allowing an electric current to flow through the first switching device 20 to the output 22 of the driver circuit 12. Where the gate-source voltage of the first switching device 20 is zero or positive, the first switching device 20 is said to be “OFF” and substantially no current flows through the first switching device 20 to the output 22. It is understood that the flow of electrical current from source to drain is dependent on the characteristic curve of the first switching device 20 relative to the applied voltages between gate-source and drain-source. It is further understood that the first switching device 20 may have any characteristic curve and switching time, as desired.

The output 22 is adapted to be electrically coupled to the load 14 and thereby transmit an electrical current to the load 14. As shown, the output 22 is in electrical communication with the supply input 18, wherein the first switching device 20 is disposed therebetween to control the flow of current between the supply input 18 and the output 22. It is understood that additional components may be in electrical communication with the output 22, as desired.

The second switching device 24 is a field-effect transistor. In the embodiment shown, the second switching device 24 is an n-channel MOSFET having a gate, a source, and a drain as known to someone skilled in the art of transistors. However, it is understood that other transistors or switches may be used to regulate the flow of current in the driver circuit 12, as desired. In the embodiment shown, the gate of the second switching device 24 is in electrical communication with the control input 26, the source of the second switching device 24 is grounded, and the drain is in electrical communication with the gate of the first switching device 20. As would be appreciated by someone skilled in the art of transistors, where a gate-source voltage of the second switching device 24 is positive, the second transistor is said to be “ON” and an electric current is allowed to flow through the second switching device 24. Where the gate-source voltage is substantially zero or negative, the second switching device 24 is said to be “OFF” and substantially no current flows through the second switching device 24. It is understood that the flow of electrical current from drain to source is dependent on the characteristic curve of the second switching device 24 relative to the applied voltages between gate-source and drain-source. It is further understood that the second switching device 24 may have any characteristic curve and switching time, as desired.

The control input 26 is adapted to receive a control signal (not shown). It is understood that the control input 26 may be in electrical communication with any device, component, or system adapted to transmit the control signal. For example, the control input 26 may be in electrical communication with a micro-controller, wherein the micro-controller generates and transmits the control signal. Other controllers, systems, and devices may be used, as desired.

The protection circuit 16 includes an exclusive-OR gate (XOR) 28, a filter 30, and a third switching device 32. The XOR gate 28 includes a first input node 34, a second input node 36, and an output node 38. The XOR gate 28 is a digital logic gate that implements exclusive disjunction. Specifically, a logic HIGH signal is present on the output node 38 if one, and only one, of the input nodes 34, 36 receives a logic HIGH signal. Where both input nodes 34, 36 are LOW or both input nodes 34, 36 are HIGH, a logic LOW signal is transmitted to the output node 38. It is understood that the voltage levels represented by the logic HIGH and logic LOW signals are dependent upon the particular electrical characteristics of the XOR gate 28 such as threshold voltage, for example. It is further understood that the XOR gate 28 n ay have any electrical characteristics, as desired.

The filter 30 is in electrical communication with the output node 38 of the XOR gate 28 and the third switching device 32. As such, the filter 30 provides control over the voltage and current levels along a signal line 39 coupled to the output node 38 of the XOR gate 28 and the third switching device 32. In certain embodiments, the filter 30 may include components to suppress conducted interference present on the signal line 39 coupled to the output node 38 of the XOR gate 28. As shown, the filter 30 includes a plurality of resistors R7, R8 and a capacitor C1. The capacitor C1 is connected in parallel with a resistor R8, wherein the capacitor C1 and the resistor R8 have pre-determined characteristics to define a pre-determined delay or effective “time-constant”. As can be appreciated by someone skilled in the art of transistors, the filter 30 in protection circuit 16 does not technically have a time-constant due to the presence of the third switching device 32. Specifically, it is understood that the base-emitter junction of the third switching device 32 represents a diode that militates against the output node 38 going above ˜0.6V. However, resistor R7, resistor R8, and capacitor C1 provide a delay or effective “time constant” to prevent third switching device 32 from turning on during a first pulse. However, it is understood that components and electrical arrangements may be used, as desired. It is further understood that the filter 30 may have any delay or effective “time constant”, as desired. In certain embodiments, the delay of the filter 30 is greater than the switching times of each of the switching devices 20, 24, 32.

The third switching device 32 is a bipolar junction transistor (BJT). In the embodiment shown, the third switching device 32 is an NPN BJT having a base, a collector, and an emitter, as known to someone skilled in the art of transistors. It is understood that the collector current of the third switching device 32 is proportional to and controlled by the base current (I_{C}=βI_{B}) in the active region and strongly dependent on the collector-emitter voltage (V_{CE}) in the saturation region. As shown, the base of the third switching device 32 is in electrical communication with the output node 38 of the XOR gate 28. Specifically, the base of the third switching device 32 is coupled to the signal line 39. The emitter of the third switching device 32 is coupled to a ground. The collector of the third switching device 32 is in electrical communication with the gate of the second switching device 24.

In use, the first input node 34 of the XOR gate 28 is in electrical communication with the output 22 of the driver circuit 12 and the second input node 36 is in electrical communication with the control input 26. Where the signal at the input nodes 34, 36 of the XOR gate 28 are both logic HIGH or both logic LOW, the XOR gate 28 transmits a logic LOW to the output node 38 and the third switching device 32 is “OFF”. Where one and only one of the signals at the input nodes 34, 36 is logic HIGH, a logic HIGH signal is transmitted to the output node 38 of the XOR gate 28, through the filter 30, and to the base of the third switching device 32. Once the high signal is applied to the base, the third switching device 32 is switched “ON” and the gate of the second switching device 24 is effectively grounded. As a result, the second switching device 24 is switched “OFF”, thereby allowing a positive voltage to be applied to the gate of the first switching device 20. Accordingly, the first switching device 20 is switched “OFF” and substantially no electric current is transmitted from the supply input 18 to the output 22 of the driver circuit 12.

The protection circuit 16 according to the present invention provides a means to protect the high side driver 10 from a short to ground without software intervention. Further, the protection circuit 16 minimizes the required number of components to achieve short-to-ground protection for the high side driver 10.

From the foregoing description, one ordinarily skilled in the art can easily ascertain the essential characteristics of this invention and, without departing from the spirit and scope thereof, make various changes and modifications to the invention to adapt it to various usages and conditions.

What is claimed is:

1. A protection circuit for a high side driver comprising:
an exclusive-OR gate adapted to receive a first input and a second input, analyze each of the inputs and transmit an output in response to the analysis of the inputs, wherein the first input represents an electric power output of the high side driver and the second input represents a control signal for operating the high side driver; and
a switching device adapted to control an electrical output of the high side driver in response to the output of the exclusive-OR gate.

2. The protection circuit according to claim 1, wherein the switching device is a transistor having a pre-determined switching time.

3. The protection circuit according to claim 1, wherein the switching device is at least one of a field-effect transistor and a bi-polar junction transistor.

4. The protection circuit according to claim 1, further comprising a filter having a pre-determined delay for regulating the output of the exclusive-OR gate.

5. The protection circuit according to claim 4, wherein the filter includes at least one of a capacitor and a resistor.

6. The protection circuit according to claim 2, further comprising a filter having a pre-determined delay for regulating the output of the exclusive-OR gate, wherein the delay is greater than the switching time of the switching device.

7. The protection circuit according to claim 6, wherein the filter includes at least one of a capacitor and a resistor.

8. A high side driver comprising:
a driver circuit including a first switching device and a second switching device, wherein the first switching device and the second switching device cooperate to control an electrical output of the high side driver; and
a protection circuit including:
an exclusive-OR gate adapted to receive a first input and a second input, analyze each of the inputs and transmit an output in response to the analysis of the inputs, wherein the first input represents the electric power output of the high side driver and the second input represents a control signal for operating the high side driver; and
a third switching device in electrical communication with at least one of the first switching device and the second switching device and adapted to control the at least one of the switching devices in response to the output of the exclusive-OR gate.

9. The high side driver according to claim 8, wherein at least one of the first, second, and third switching devices is a transistor having a pre-determined switching time.

10. The high side driver according to claim 8, wherein each of the first, second, and third switching devices is at least one of a field-effect transistor and a bi-polar junction transistor.

11. The high side driver according to claim 8, further comprising a filter having a pre-determined delay for regulating the output of the exclusive-OR gate.

12. The high side driver according to claim 11, wherein the filter includes at least one of a capacitor and a resistor.

13. The high side driver according to claim 9, further comprising a filter having a pre-determined delay for regulating the output of the exclusive-OR gate, wherein the delay is greater than the switching time of the at least one of the first, second, and third switching devices.

14. The high side driver according to claim 13, wherein the filter includes at least one of a capacitor and a resistor.

15. A high side driver comprising:
a driver circuit including a first transistor and a second transistor, wherein the first transistor and the second transistor cooperate to control an electrical output of the high side driver; and
a protection circuit including:
an exclusive-OR gate adapted to receive a first input and a second input, analyze each of the inputs and transmit an output in response to the analysis of the inputs, wherein the first input represents the electric power output of the high side driver and the second input represents a control signal for operating the high side driver; and
a third transistor in electrical communication with at least one of the first transistor and the second transistor and adapted to control the at least one of the switching devices in response to the output of the exclusive-OR gate.

16. The high side driver according to claim 15, wherein the first transistor is a field-effect transistor, the second transistor is a field-effect transistor, and the third transistor is a bi-polar junction transistor.

17. The high side driver according to claim 16, wherein the first, second, and third transistors have the following electrical configuration:
a source of the first transistor is coupled to a supply input of the high side driver and a drain of the first transistor is coupled to an output of the high side driver;
a source of the second transistor is coupled to a ground and a drain of the second transistor is coupled to a gate of the first transistor; and
a collector of the third transistor is coupled to the gate of the second transistor, an emitter of the third transistor is coupled to a ground, and a base of the third transistor is coupled to the output node of the exclusive-OR gate.

18. The high side driver according to claim 15, further comprising a filter having a pre-determined delay for regulating the output of the exclusive-OR gate.

19. The high side driver according to claim 18, wherein the filter includes at least one of a capacitor and a resistor.

20. The high side driver according to claim 17, further comprising a filter having a pre-determined delay for regulating the output of the exclusive-OR gate, wherein the delay is greater than the switching time of the at least one of the first, second, and third transistors.
